(19) United States
(12) Patent Application Publication
(10) Pub. No.: US 2003/0200915 A1
(43) Pub. Date: Oct. 30, 2003

(54) Production method for InP single crystal and InP single crystal

(75) Inventors: Masanori Kimura, Annaka-shi (JP); Jun Ikeda, Annaka-shi (JP)

Correspondence Address: Ronald R. Snider, Snider & Associates, P.O. Box 27613, Washington, DC, 20038-7613, US

(73) Assignee: Shin-Etsu Handotai Co., Ltd., Tokyo (JP)

(21) Appl. No.: 10/421,847

(22) Filed: Apr. 24, 2003

(30) Foreign Application Priority Data
Apr. 30, 2002 (JP) 2002-128554

(51) Int. Cl. C30B 23/00; C30B 25/00; C30B 28/12; C30B 28/14

(52) U.S. Cl. 117/84

(57) ABSTRACT

In production of the InP single crystal 10 having a crystal orientation of <100>, an angle (a cone angle) formed between an axial line of the InP single crystal 10 and a tangent to an outline of the cone portion 13 is larger than 35.3° in a section including the axial line, in a region where a diameter of the cone portion 13 is 10 mm or more and 70% or less of a diameter of the constant diameter portion 1. Furthermore, when x axis is selected in the axial direction of the InP single crystal 10 and r axis is selected in a radial direction of the InP single crystal 10, and an outline of the cone portion 13 is expressed as a function of x and r, the cone portion 13 is formed so as to satisfy a relation of 0<d²r/dx²≦0.1 in a region where a diameter of the cone portion is 10 mm or more and 70% or less of a diameter of the constant diameter portion. With this arrangement, provided are a production method for an InP single crystal capable of reducing twinning ratio in a cone portion to a lower level and an InP single crystal, in a cone portion and constant diameter portion of which formation of a twin is suppressed.

### RELATED APPLICATION

This application claims the priority of Japanese Patent Application No. 2002-128554 filed on Apr. 30, 2002, which is incorporated herein by reference.

### BACKGROUND OF THE INVENTION

1. Field of the Invention

This invention relates to a production method for an InP single crystal and an InP single crystal.

2. Description of the Related Art

An InP single crystal substrate is used as a substrate of, for example, a light emitting device or other semiconductor devices. The substrates can be obtained by slicing an ingot of InP single crystal produced with, for example, a liquid encapsulated Czochralski (LEC) method into wafer-shaped pieces. The LEC method is to bring a seed crystal in contact with an InP melt in a state where the InP melt accommodated in a crucible is encapsulated with boron oxide (B₂O₃) and to grow a single crystal by gradually pulling a seed crystal in an axial direction in the state. Since a compound semiconductor such as InP has a nature to decompose at a high temperature, not only is crystal growth performed in an atmosphere under a pressure as high as tens of atm, but decomposition of a raw material melt is also indirectly suppressed with a liquid encapsulating material. In order to grow a constant diameter portion with a desired diameter of an InP single crystal, a cone portion in which a diameter increases toward the constant diameter portion side is formed between the seed crystal and the constant diameter portion in an ingot of InP single crystal.

In a case where an InP single crystal ingot is produced with a LEC method, however, a problem has remained that a twin is easily formed in the cone portion a diameter of which greatly changes. If a twin is formed in the cone portion, no single crystal is attained in a portion grown thereafter, for example the constant diameter portion. Consequently, a yield of a single crystal product is reduced, therefore its product cost is raised. In a case where a crystal orientation of a growing InP single crystal is <100>, when, in a section including an axial line of the cone portion as shown in FIG. 6A, an angle formed between the axial line and a tangent to an outline of the cone portion (hereinafter referred to as a cone angle) is 35.3°, a twin is especially easy to be formed. Therefore, the cone portion is grown at a cone angle different from 35.3°. Furthermore, in a case where a crystal orientation of an InP single crystal in growth is <111>, a twin is easily formed in the cone portion at a cone angle of 19.5° as shown in FIG. 6B. In the following description, an angle between the axial line and above tangent of the twin in the section when the twin is formed is referred to as a twinning angle.

If a cone portion is grown with a cone angle being larger than a twinning angle in order to suppress formation of a twin, the cone angle coincides with the twinning angle without fail while growth transitions from the cone portion to a constant diameter portion; which has led to a fear to raise twinning ratio. Therefore, in a prior art practice, a cone portion was grown so that a cone angle was smaller than the twinning angle. According to this operation, there is absolutely no chance that a cone angle coincides with the twinning angle, while growth transitions from the cone portion to the constant diameter portion, thereby suppressing twinning. Even if a cone portion is grown in such a way, however, twinning-free has not necessarily been ensured in the cone portion, but twinning ratio in the cone portion has been unable to be sufficiently decreased.

### SUMMARY OF THE INVENTION

It is an object of the invention to provide a production method for an InP single crystal capable of reducing twinning ratio in a cone portion to a lower level and to provide an InP single crystal, in a cone portion and constant diameter portion of which twinning is suppressed.

In order to achieve the object, a first production method for an InP single crystal of the invention is a production method for an InP single crystal having a cone portion and a constant diameter portion subsequent to the cone portion with an liquid encapsulated Czochralski method, wherein when, in a section including an axial line of the InP single crystal, an angle formed between the axial line and a tangent to an outline of the cone portion is a cone angle, a period in which the cone angle is larger than a twinning angle is set during growth of the cone portion and in addition, during the period, a diameter increasing rate of the cone portion is gradually raised.

Furthermore, a first InP single crystal of the invention includes: a cone portion and a constant diameter portion subsequent thereto, and when, in a section including an axial line of the InP single crystal, an angle formed between the axial line and a tangent to an outline of the cone portion is a cone angle, a region in which a diameter increasing rate of the cone portion gradually increases toward the constant diameter portion side is present in a region in which the cone angle is larger than a twinning angle.

The inventors have studied, giving a second look, a method for forming the cone portion with a cone angle being larger than a twinning angle, which was not used in a prior practice, to investigate a relationship of a magnitude of the cone angle and a change rate thereof with twinning ratio in InP signal crystal. As a result, the inventors have found that twinning ratio can be suppressed by controlling a melt temperature so as to cause a diameter increasing rate of the cone portion to gradually increase even during a period when the cone angle is larger than a twinning angle in growth of the cone portion, leading to completion of the invention. The reason why twinning is suppressed by a method of the invention is that a remelting phenomenon at a solid-liquid interface can be suppressed by controlling a melt temperature as described above. According to the invention, twinning ratio decreases to a lower level than according to a method forming a cone portion with a cone angle smaller than a twinning angle, adopted traditionally. An InP single crystal produced in this way has a region, in which a cone angle is larger than a twinning angle, and in which a diameter increasing rate increases toward the constant diameter portion side.

A twin is formed originating from a twin nucleus that is formed when an atomically flat growth surface called a edge facet is formed at a solid-liquid interface in a growth course of an InP single crystal, and in which nucleus there exist atomic arrangements different from each other on both sides of a twin plane, which are not an atomic arrangement with a normal orientation. Especially, a twin nucleus is easily formed after supercooling caused by a remelting phenomenon with top priority. By the inventors, it has been found to be effective that in order to suppress twinning, there is provided a range in which a cone angle is larger than a twinning angle and a melt temperature is controlled so that a cone angle gradually increases in the range. That is, while in order to gradually increase a cone angle, a melt temperature has to be gradually lowered and a remelting phenomenon at a solid-liquid interface becomes hard to occur by controlling a melt temperature in this way, thereby suppressing occurrence of a twin nucleus.

On the other hand, the reason why a method forming a cone portion with a cone angle larger than a twinning angle has not been used is that there arises a portion in which the cone angle and the twinning angle are equal to each other without fail during a course of transition in growth of an InP single crystal from the cone portion to a constant diameter portion. It has been found that in a case where a cone portion is formed applying the invention, however, twinning is suppressed even in a region where a cone angle becomes equal to the twinning angle during a period when the cone portion is transitioned to the constant diameter portion in growth of an InP single crystal. That is, if a cone portion is formed according to the invention, a remelting phenomenon becomes hard to occur since the cone portion having already been grown has a sufficient temperature gradient when crystal growth transitions from the cone portion to the constant diameter portion, and twinning is suppressed even if the cone angle becomes equal to the twinning angle.

A twin is easily formed if a temperature gradient in growing crystal is small. To be concrete, a twin is conspicuously formed in a period till a diameter of the cone portion becomes 70% of a diameter of the constant diameter portion. Since a region in which a diameter of the cone portion is less than 10 mm is in the vicinity of a seed crystal, there inevitably exist a period when the cone angle is smaller than the twinning angle while a diameter of the cone portion is increased in a first stage of forming the cone portion. Therefore, it is preferable to cause a cone angle to be larger than the twinning angle through a period from when a diameter of the cone portion takes 10 mm till a diameter thereof reaches 70% of a diameter of the constant diameter portion. Furthermore, it is preferable to gradually increase a diameter increase rate of the cone portion in the range. On the other hand, after a diameter of the cone portion reaches 70% of a diameter of the constant diameter portion, owing to the temperature gradient being sufficient for above cone portion, a remelting phenomenon is hard to occur and twinning is easily suppressed. Furthermore, such a period is also a period when a crystal in growth transitions from the cone portion to the constant diameter portion. On this occasion, it is preferably that a diameter increasing rate of the cone portion (that is a cone angle) is gradually decreased to shift to growth of the constant diameter portion. If a diameter increasing rate of the cone portion is rapidly decreased in a part excessively close to the diameter of the constant diameter portion, there also arise a fear of occurrence of not only a twin but also other dislocations.

Furthermore, according to the inventors, it has been found that in order to suppress occurrence of a twin in the cone portion, it is effective to merely increase a cone angle to a value larger than the twinning angle in a range where a temperature gradient in the cone portion is small, that is a region where a diameter of the cone portion is 10 mm or more and 70% or less of a diameter of the constant diameter portion. That is to say, a second production method for an InP single crystal of the invention is a production method for an InP single crystal having a cone portion and a constant diameter portion subsequent to the cone portion with an liquid encapsulated Czochralski method, wherein when, in a section including an axial line of the InP single crystal, an angle formed between the axial line and a tangent to an outline of the cone portion is a cone angle, the cone angle is larger than the twinning angle through a period from when a diameter of the cone portion takes 10 mm till the diameter thereof reaches 70% of a diameter of the constant diameter portion.

Furthermore, a second InP single crystal of the invention includes: a cone portion and constant diameter portion subsequent thereto, and when, in a section including an axial line of the InP single crystal, an angle formed between the axial line and a tangent to an outline of the cone portion is a cone angle, the cone angle is larger than the twinning angle in a region where a diameter of the cone portion is 10 mm or more and 70% or less of a diameter of the constant diameter portion.

If a melt temperature is controlled so that a cone angle is larger than a twinning angle through the range where a temperature gradient is easy to be the smallest, a temperature gradient in the cone portion in the range can be larger and a melting phenomenon is in turn suppressed, thereby enabling occurrence of a twin to be suppressed. Since no period is available in which the cone angle is equal to the twinning angle in a quite wide range in which a diameter of the cone portion is 10 mm or more and 70% or less of a diameter of the constant diameter portion, a factor to produce a twin during formation of the cone portion is removed. Furthermore, after a diameter of the cone portion exceeds 70% of a diameter of the constant diameter portion, the cone portion having formed also has a sufficient temperature gradient, thereby suppressing twinning if a cone angle takes a twinning angle.

Furthermore, in the first and second production methods for an InP single crystal, and the first and second InP single crystals, not only is an effect to decrease twinning ratio realized but also a growth time required for formation of the cone portion also becomes shorter compared with a case where a cone angle becomes smaller than a twinning angle by increasing the cone angle to a value larger than the twinning angle. With increase in diameter of the constant diameter portion of an InP single crystal, it takes a longer time to form the cone portion. Therefore, an effect that reduction is ensured in time required for formation of the cone portion becomes more conspicuous as a diameter of an InP single crystal increases.

To be concrete, it is preferable to form the cone portion according to the following method. That is, when in a section including an axial line of an InP single crystal, x axis is selected in the axial direction of the InP single crystal and r axis is selected in a radial direction of the InP single crystal, and an outline of the cone portion is expressed as a function of x and r, the cone portion is formed so that the function expressing an outline of the cone portion satisfies a relation of 0<d²r/dx²≦0.1 through a period from when a diameter of the cone portion takes 10 mm till the diameter thereof reaches 70% of a diameter of the constant diameter portion. When, in this way, an outline of the cone portion is expressed as a function of r and x, that is r=f(x), d²r/dx² expresses an increasing rate of an inclination of a tangent of the outline, that is an increasing rate of a cone angle. That is to say, it is preferable that not only is a melt temperature controlled (0<d²r/dx²) so as to gradually increase a cone angle, but an increasing rate (d²r/dx²) of the cone angle is also restricted within 0.1. If a melt temperature is lowered so that d²r/dx² exceeds a value of 0.1, a great supercooling occurs in the melt. Therefore, not only is twinning ratio raised, but the great supercooling also acts as factors causing other dislocations.

Such a production method for an InP single crystal is especially effective in a case where a growth orientation of the InP single crystal in growth is <100>. That is, a production method of the invention is to grow an InP single crystal with a crystal orientation of <100>, wherein a twinning angle can be 35.3°. It has been known that, in a case where a crystal orientation is <100>, a twin is formed in a direction with an angle to the axial line of the InP single crystal of 35.3°.

In the first and second production methods for an InP single crystal, and the first and second InP single crystals, it is preferable to form the cone portion so that a cone angle does not exceed 70° while satisfying the conditions as described. With so a great change in diameter of the cone portion that a cone angle exceeds 70° during growth of the cone portion, a change in temperature at a solid-liquid interface between an InP single crystal and a melt increases and exceeds a prescribed value. Therefore, since a supercooling phenomenon occurs with ease at the solid-liquid interface even if a method of the invention as described above is adopted, which is not preferable.

In an InP single crystal of the invention produced with a method as described above, almost no twin is formed in the cone portion and constant diameter portion. Therefore, a yield of an InP signal crystal is raised.

### BRIEF DESCRIPTION OF THE DRAWINGS

FIG. 1A is an outline of an InP single crystal of the invention;

FIG. 1B is a graph which shows relation between crystal radius and crystal axis in FIG. 1A for above mentioned cone angle;

FIG. 2 is a schematic view of a LEC growth furnace used in a production method of the invention;

FIG. 3A is a graph and a view showing a heater pattern and an outline of an InP single crystal for applied prior art;

FIG. 3B is a graph and a view showing a heater pattern and an outline of an InP single crystal for applied the invention;

FIG. 4 is graphs showing results of Experiment 1;

FIG. 5 is graphs showing results of Experiment 2;

FIG. 6A is view describing twinning angles in a concrete manner in a case where a crystal orientation of a growing InP single crystal is <100>; and

FIG. 6B is view describing twinning angles in a concrete manner in a case where a crystal orientation of a growing InP single crystal is <111>.

### DESCRIPTION OF THE PREFERRED EMBODIMENTS

Description will be given of embodiments of the invention below with reference to the accompanying drawings.

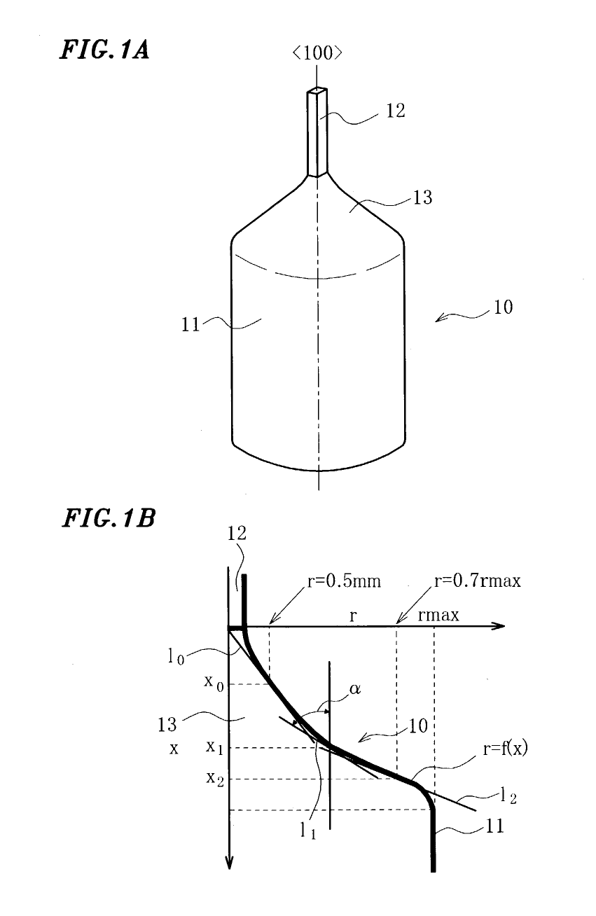

FIG. 1A is to show an InP single crystal 10 of the invention produced with a method of the invention. The InP single crystal 10 is constituted of a seed crystal 12; a cone portion 13 increasing a diameter thereof as it grows; and a constant diameter portion 11, grown following the cone portion 13 and having a constant diameter. Furthermore, a crystal orientation of the InP single crystal 10 is <100> and a twinning angle this time is 35.3°. A diameter of the constant diameter portion 11 is 2 to 3 inch (about 50.8 mm to about 76.2 mm).

FIG. 1B is to show a section including an axial line of the InP single crystal 10. An angle formed between the axial line (x axis) of the InP single crystal 10 and a tangent (for example, I₁) to an outline of the cone portion 13 is defined as a cone angle (α). There exists a range in which the cone angle takes a value larger than the twinning angle in the cone portion 13 of the InP single crystal 10. To be concrete, a cone angle is larger than the twinning angle, to be concrete, 35.3° in a region where a diameter of the cone portion 13 is 10 mm or more and 70% or less of a diameter of the constant diameter portion 11. Furthermore, a diameter increasing rate in the axial direction of the cone portion 13 gradually increases toward the constant diameter portion 11 side.

In this embodiment, when in a section including the axial line of the InP single crystal 10, x axis is selected in the axial direction thereof and r axis is selected in a radial direction, and an outline of the cone portion 13 is expressed as a function of x and r, the function expressing the outline of the cone portion 13 satisfies a relation of 0<d²r/dx²≦0.1 in a region (5 mm≦r≦0.7 rmax) where a diameter of the cone portion 13 is 10 mm or more (a radius of the cone portion is 5 mm or more) and 70% or less of the diameter (2 rmax) of the constant diameter. Note that in the cone portion 13, a cone angle is 70° or less. To be more concrete, as shown in FIG. 1B, when a diameter of the cone portion 13 is 10 mm, x is defined as x₀ and a tangent to r=f(x) is defined as l₀ at x=x₀, an angle formed between the tangent l₀ and x axis is larger than 35.3° and furthermore, an angle formed between a tangent (l₂) to r=f(x) and x axis takes a value of 70° or less when a diameter of the cone portion 13 is 70% of the diameter of the constant diameter portion 11 (x=x₂). Inclinations of the tangents (l₀, l₁ and l₂) each are expressed with dr/dx and an inclination of a tangent (l₀, l₁ and l₂) increases as x increases (0<d²r/dx²). However, in a region where a diameter of the cone portion 13 exceeds 70% (0.7 rmax<r≦rmax), an increasing rate of a cone angle, that is d²r/dx², gradually decreases toward the constant diameter portion 11 side. Note that microscopically, an outline of the cone portion 13 does not change in a continuous manner. Therefore, in this specification, continuity of the outline of the cone portion 13 is regarded to be not problematical in a region where a very small range of x (dx) is less than 0.1 mm.

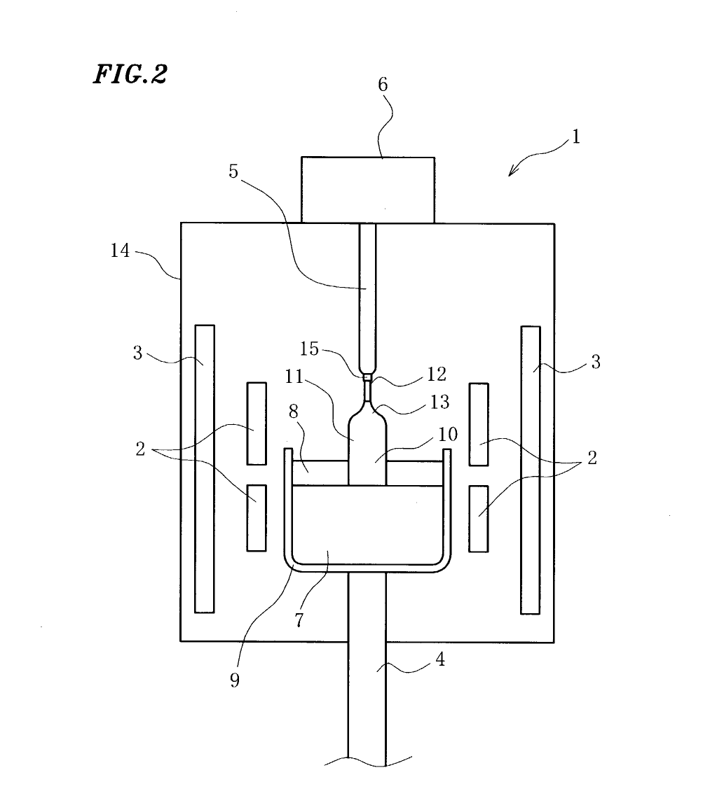

Then, description will be given of a production method for an InP single crystal 10 as described above. FIG. 2 shows an outline of a growth furnace 1 according to a LEC method (hereinafter referred to as simply a LEC growth furnace 1) for implementing a production method for an InP single crystal of the invention. The LEC growth furnace 1 includes a high pressure furnace 14 in which there is disposed a crucible 9, accommodating a raw material melt 7 of InP, and made of, for example, quartz or PBN (Pyrolytic Boron Nitride). A heater 2 for heating the raw material melt 7 accommodated in the crucible 9 is arranged around the outer periphery of the crucible 9. In a situation where the InP single crystal is grown, the heater 2 is supplied with power from electrodes by a heating control mechanism not shown to generate heat and a temperature of the raw material melt 7 is controlled by adjusting the power. While the heater 2 can be made of, for example, graphite, the heater coated with PBN can also be used in a case where doping of carbon into the InP single crystal 10 is intentionally suppressed.

An in-furnace insulating material 3 is placed between the heater 2 and a furnace wall of the high pressure furnace 14 in order to protect a metal furnace wall and to thermally insulate a space inside the high pressure furnace 14 with efficiency. The insulating material 3 can also be made of graphite and furthermore, the graphite insulating material coated with PBN may also be used. The crucible 9 placed almost in the center of the high pressure furnace 14 is supported by a crucible support shaft 4 at the bottom thereof and freely movable, upward and downward, and freely rotatable by a crucible driving mechanism (not shown) attached to the lower end portion of the crucible support shaft 4. With such construction and mechanism, a liquid surface of the raw material melt 7 can be held at a prescribed height and the crucible 9 can be rotated at a desired rate and in a desired direction during growth of the InP single crystal 10. Furthermore, a pressure control apparatus not shown is equipped to the growth furnace 1 in order to adjust a pressure in the high pressure furnace 14 and during growth of the InP single crystal 10, the pressure in the high pressure furnace 14 is adjusted by a pressure control mechanism thereof.

A pulling shaft 5 used for pulling the InP single crystal 10 from the raw material melt 7 extends in the high pressure furnace 14 downward from a ceiling portion of the high pressure furnace 14 and a pulling shaft driving mechanism not shown is equipped outside the high pressure furnace 14. A seed crystal holder 15 for holding the seed crystal 12 is attached at the lower end of the pulling shaft 5 engaged in the pulling shaft driving mechanism and the seed crystal 12 is anchored to the seed crystal holder 15; and the distal end of the seed crystal 12 is brought into contact with the surface of the raw material melt 7, fused therein and pulled therefrom, thereby growing the InP single crystal 10. The pulling shaft 5 is not only movable in an upward or downward direction, but also rotatable and a rotational rate and the like are controlled by a crystal rotation control mechanism not shown.

Note that the top of the raw material melt 7 in the crucible 9 is covered with a liquid encapsulating material 8 of boron oxide (B₂O₃). Since a compound semiconductor such as InP is very easily decomposed, decomposition of InP in the raw material melt 7 is suppressed with the liquid encapsulating material 8. The liquid encapsulating material 8 has a melting point lower than InP polycrystal raw material and is melted prior to the start of melting of the raw material; therefore, the decomposition can be suppressed by the liquid encapsulating material 8 even when a temperature of raw material chunk reaches a decomposition temperature thereof.

A load cell 6 measuring a weight of the crystal in growth is installed at the top portion of the pulling shaft 5 for pulling the crystal in the LEC growth furnace 1 used in the invention. A change in weight of the InP single crystal 10 over an elapsed time can be measured by the load cell 6. There is equipped a growth rate arithmetic mechanism not shown calculating a growth rate of the InP single crystal 10 based on a position of the liquid surface of the raw material melt 7, moving speeds in an upward or downward direction of the crucible 9 and the pulling shaft 5, and other parameters. Furthermore, there are equipped a cone angle arithmetic mechanism calculating a change in diameter of the InP single crystal 10, that is a cone angle in formation of the cone portion, based on results obtained by the load cell 6 and the growth rate arithmetic mechanism and a cone angle change rate arithmetic mechanism calculating a change rate of a cone angle for a unit growth length of the InP single crystal 10 based on an obtained cone angle and a position of the InP single crystal 10. For example, the load cell 6, the pulling shaft driving mechanism, the crucible driving mechanism and others are connected to a computer not shown and a CPU built in the computer can play roles of the growth rate arithmetic mechanism, the cone angle arithmetic mechanism and the cone angle change rate arithmetic mechanism, described above. The computer is connected to the heating control mechanism and controls an amount of heat generated by the heater 2 based on arithmetic results in the CPU according to a heating control program stored in a ROM in the computer.

In the LEC growth furnace 1 with such a construction, the crucible 9 placed inside of the high pressure furnace 14 is filled with raw material chunks of InP and boron oxide as the liquid encapsulating material 8 is further placed on the top of the raw material chunks. Then, after the interior of the furnace is filled with an inert gas, such as nitrogen gas or argon gas, the heater 2 in the high pressure furnace 14 is caused to generate heat to heat the raw material chunks of InP to a temperature of the order of 1060° C., which is the melting point of InP, or higher into the raw material melt 7. Through the operation, the interior of the high pressure furnace 14 is in a high pressure atmosphere at a pressure of 27 atm, which is a vapor pressure of InP, or higher so as not to decompose InP in the raw material melt. To be concrete, a pressure in the high pressure furnace 14 is set as high as 40 atm or higher.

After all the raw material chunks accommodated in the crucible 9 are molten, a temperature of the raw material melt 7 is adjusted to a value suitable for growth of an InP single crystal 10 and the pulling shaft 5 with the seed crystal holder 15 holding the seed crystal 12 at the lower end thereof is moved downward to cause the distal end of the seed crystal 12 to be in contact with the surface of the raw material melt 7. Then the seed crystal 12 is pulled under control of a temperature of the melt with the heater 2, control of rotational speeds of the seed crystal 12 and the crucible 9 and control of a pulling speed of the crystal, thereby growing the InP single crystal 10 at the lower end of the seed crystal 12.

In order to grow the InP single crystal 10 having the constant diameter portion 11 of a prescribed diameter at the lower end of the seed crystal 12, firstly formed is the cone portion 13 a diameter of which gradually increases toward the constant diameter portion 11. Through the operation, in order to realize a production method of the invention, a heating pattern of the heater 2 is controlled by the heating control mechanism not shown so as not to form a twin in the cone portion 13, while monitoring a diameter, a cone angle and increasing rates thereof and the like of the cone portion 13 obtained with the above arithmetic mechanisms. When the single crystal grows and reaches a prescribed diameter in formation of the cone portion 13, increase in diameter of the cone portion 13 is ceased, followed by growth of the InP single crystal 10 at a prescribed constant diameter; thereby enabling formation of the constant diameter portion 11 of the InP signal crystal 10.

After the constant diameter portion 11 with a constant diameter is pulled over a desired length thereof, a diameter of the InP single crystal 10 is gradually reduced to form a tail portion so that no dislocation is formed by a change in temperature in separation of the InP single crystal 10 from the raw material melt 7 and thereafter, the InP single crystal 10 is separated from the melt and slowly pulled upward to cool the crystal down to a temperature closed to ordinary temperature, thereby completing the growth.

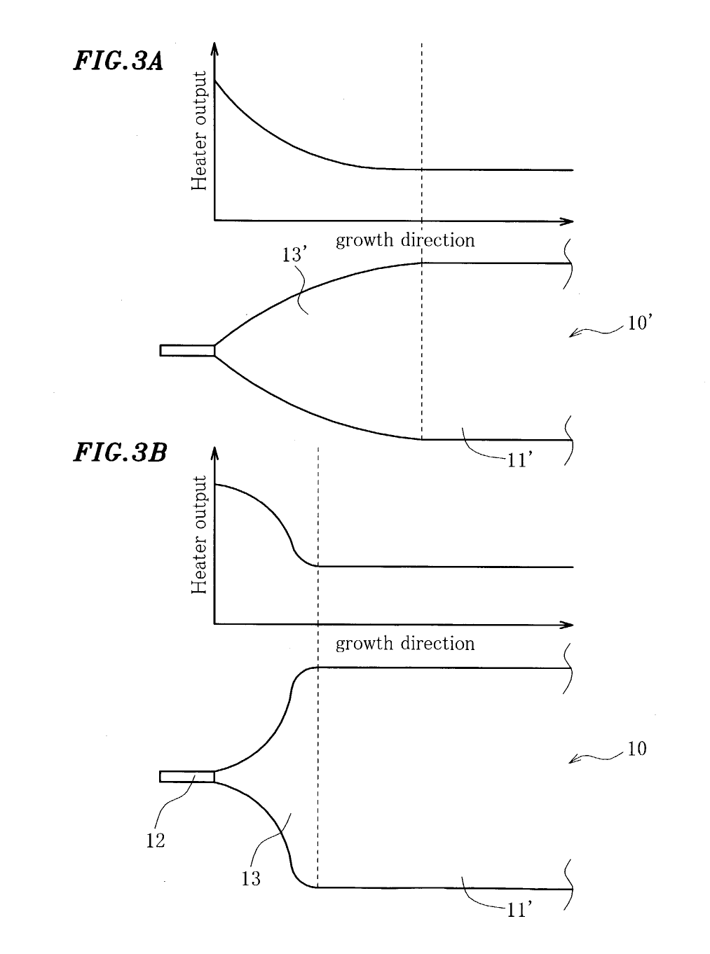

Description will be given of a heating pattern of the heater 2 for realization of a production method of the invention below. FIG. 3A and FIG. 3B are to describe a heating pattern of the invention and a prior art heating pattern by comparison with each other. In a case where a cone angle is set smaller than a twinning angle as done in a prior art practice to form the cone portion 13′ of the InP single crystal 10′, temperature control of the raw material melt has been performed with a heating pattern as shown in FIG. 3A. That is to say, as growth of the cone portion 13′ progresses, an output of the heater 2 is gradually reduced. As growth of the cone portion 13′ further progresses, a decreasing rate of output of the heater is gradually reduced and when a diameter of the cone portion 13′ reaches a desired diameter, an output of the heater is controlled so as to be constant to form the constant diameter portion 11′. By doing so, the InP single crystal 10 of a shape as shown in FIG. 3A is obtained.

On the other hand, in a production method of the invention, the cone portion 13 is formed according to a heating pattern as shown in FIG. 3B. While a heater output is gradually reduced with growth of the cone portion 13 similarly to FIG. 3A, the heating pattern of FIG. 3B is different from the heating pattern of FIG. 3A in that a decreasing rate of the heater output is increased with growth of the cone portion 13. Furthermore, when a diameter of the cone portion 13 reaches 10 mm, a melt temperature is adjusted in the first stage of formation of the cone portion 13 so that a cone angle has been larger than a twinning angle. By gradually increasing a decreasing rate of a heater output in this way, it is possible to realize a way that a diameter increasing rate gradually increases in the cone portion 13 as shown in FIG. 3B. Then, after a diameter of the cone portion 13 exceeds 70% of the diameter of the constant diameter portion, a decreasing rate of a heater output is gradually decreased to thereby gradually decrease a diameter increasing rate of the cone portion 13 and then, a heater output is controlled at a constant value to thereby shift from the growth of the cone portion to the constant diameter portion.

Note that, while concrete numerical values of a heater output, a decreasing rate thereof and the like cannot be definitely described here because of differences in heating characteristics or the like of a LEC growth furnace 1 in use according to a kind or a construction thereof, the heater output, the decreasing rate thereof and the like can are empirically determined according to thermal characteristics of the LEC growth furnace 1 in use so that a cone angle is larger than a twinning angle and 70° or less and an increasing rate (d²r/dx²) of a cone angle satisfies a relation of 0<d²r/dx²≦0.1 in a period when a diameter of the cone portion 13 is 10 mm or more and 70% or less of a diameter of the constant diameter portion 11. By setting heating control program described above so as to be adapted to a heating pattern empirically determined in this way and growing the InP single crystal 10 according to the program, plural InP single crystals 10 can be produced in the same conditions.

While the embodiment of the invention is shown in the above description, the invention is not limited to this. For example, while in this embodiment, description is given of production of an InP single crystal with a crystal orientation of <100>, the invention can also be applied to production of an InP single crystal with a crystal orientation of <111>. In this case, a twinning angle is 19.5°.

### EXAMPLES

The following experiments were conducted in order to investigate an effect of the invention. InP single crystal was produced using a LEC growth furnace equipped with: a load cell measuring a weight of a crystal; an arithmetic mechanism calculating a change in diameter from a crystal weight detected by the load cell; and an arithmetic mechanism calculating an increasing rate of a change in diameter for a unit growth length of the crystal from the change in diameter and a moving amount of the crystal.

At first, 1000 g of InP polycrystal raw material is put into a quartz crucible of 100 mm in diameter and 320 g of B₂O₃ is placed on the raw material. InP single crystals each with a diameter of 50 mm in the constant diameter portion, and a crystal orientation of <100> were pulled in various different sets of conditions for forming the cone portion in an atmosphere of 100% nitrogen under a pressure of 50 atm in the LEC furnace. Note that in pulling of InP single crystals, other conditions were commonly applied that a pulling rate of a seed crystal is 10 mm/hr, a rotational rate thereof is 10 rpm and a rotational rate of the crucible was 30 rpm in a direction opposed to the rotational direction of the seed crystal.

### Empirical Example 1

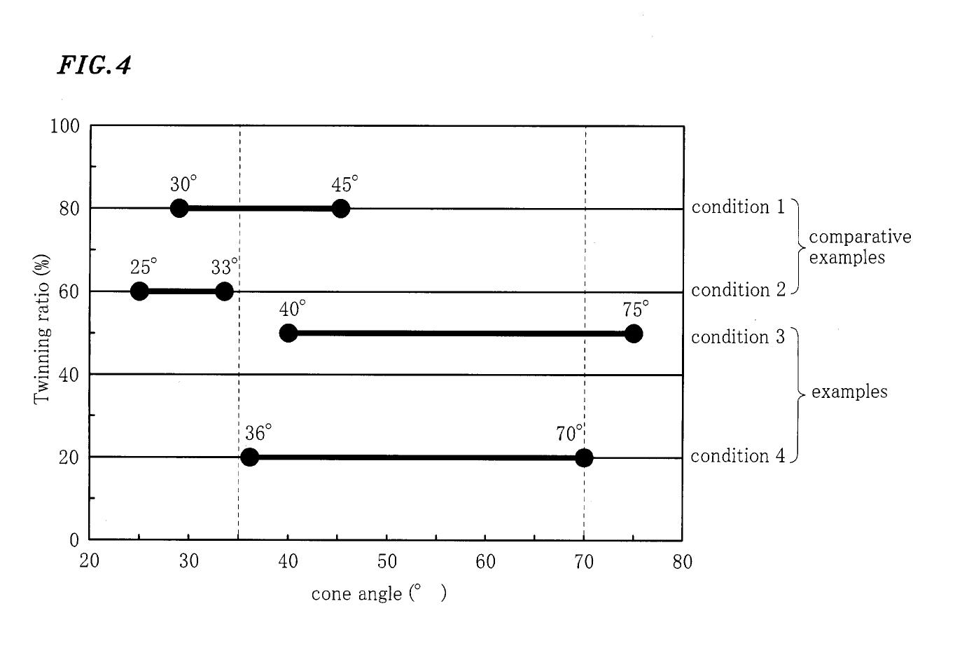

Twinning ratio was compared with each other in a case where 20 InP single crystals were grown in conditions with changes in range of a cone angles during formation of a cone portion. Results are shown in FIG. 4. Ranges of cone angles were to be measured in the range of 10 mm or more and 35 mm or less in diameter of the cone portion. Under conditions 3 and 4, the cone portion was formed so that a diameter increasing rate thereof gradually increases in the range of from 10 mm or more and 35 mm or less in diameter thereof, while under conditions 1 and 2, the cone portion was formed so that a diameter increasing rate thereof gradually decreases in the above range. The conditions 1 and 2 were conducted as comparative examples and the conditions 3 and 4 were conducted as examples of this invention. According to FIG. 4, the condition 1 showed the most high incidence of a twin. That is, this is because there exists a period when a cone angle coincides with a twinning angle (35.3°) while a diameter of the cone portion is in the range of 10 mm or more and 35 mm (70% or less of a diameter of the constant diameter portion) or less in diameter of the cone portion and a diameter increasing rate of the cone portion gradually decreases in the range. Since, in the condition 2, a cone angle is smaller than a twinning angle at all times, twinning ratio is lower than in the condition 1. In the conditions 3 and 4, which fall within the scope of the invention, however, it is found that twinning ratio is further lower. This is because a cone angle is larger than a twinning angle in the range of 10 mm or more and 35 mm or less in diameter of the cone portion and a diameter increasing rate of the cone portion increases in the range. It is found, by comparison between the conditions 3 and 4, that twinning ratio becomes further lower by restricting a range of cone angles to 70° or lower.

### Empirical Example 2

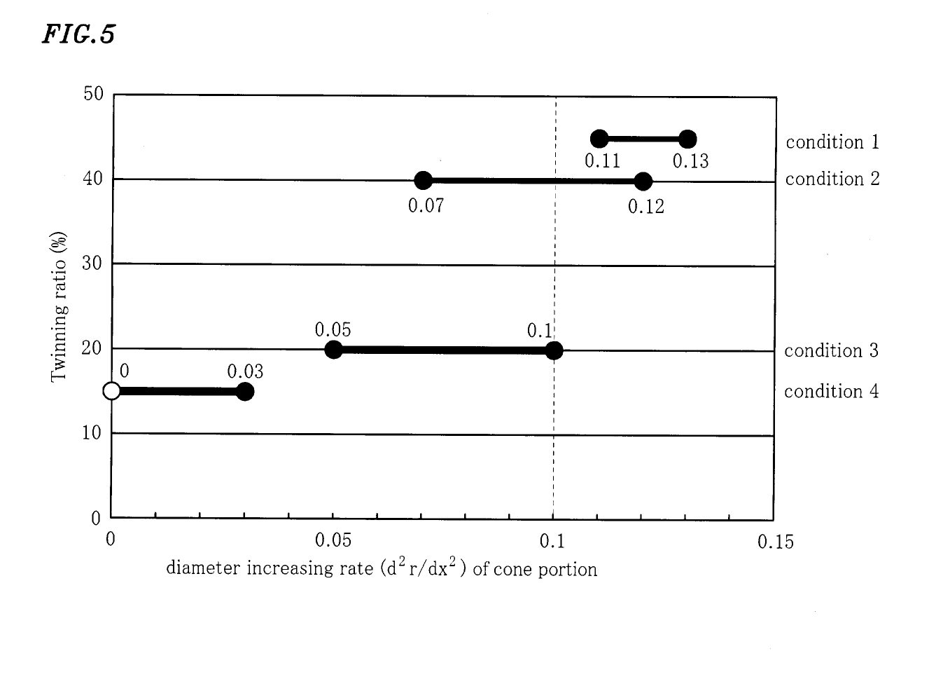

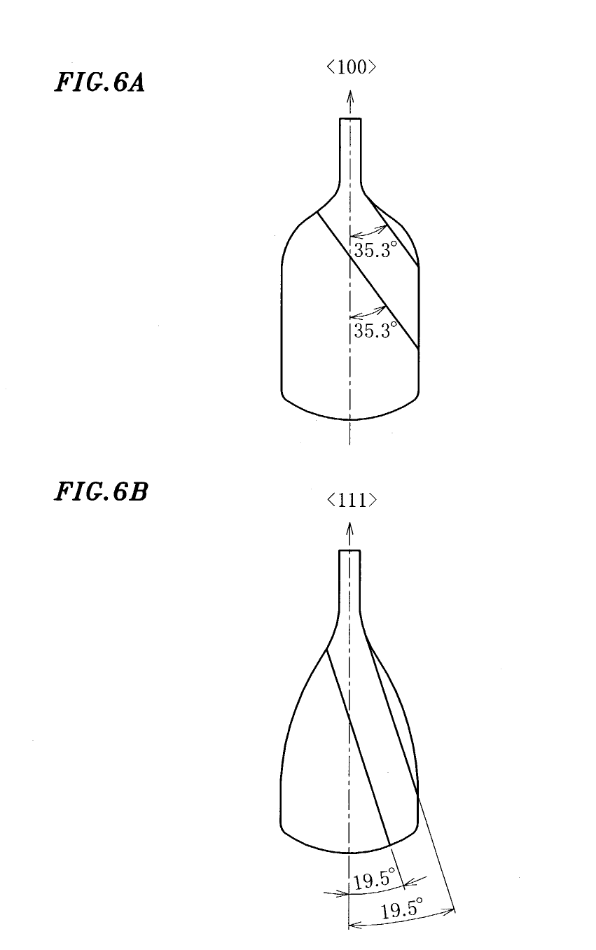

Investigation was conducted about twining ratio in a case where 20 InP single crystals were grown under various conditions obtained by changing a diameter increasing rate (d²r/dx²) of the cone portion while holding a cone angle so as to be larger than a twinning angle (35.3°) and to be 70° or less in a period when a diameter of the cone portion is in the range of 10 mm or more and 35 mm or less. Results are shown in FIG. 5. Note that a value of d²r/dx² is not constant during formation of the cone portion, but has a spread with a range. It is found from FIG. 5 that as a value of d²r/dx² is smaller, twinning ratio decreases. Furthermore, in the conditions 3 and 4 wherein a range of values of d²r/dx² is 0.1 or less, twinning ratio is reduced to a half or less compared with cases in the conditions 1 and 2 where a value of d²r/dx² exceeds 0.1.

According to the experiments, it was shown that twinning ratio decreases by controlling a melt temperature so that a diameter increasing rate of the cone portion gradually increases even in a period when a cone angle is larger than a twinning angle. Furthermore, it was shown that twinning ratio decreases by controlling a melt temperature so that a cone angle is larger than a twinning angle during a period when a diameter of the cone portion is in the range of 10 mm or more and 35 mm or less. Besides, it was shown that twinning ratio decreases by defining an increasing rate (d²r/dx²) of a diameter of the cone portion in the range of 0<d²r/dx²<0.1. An InP single crystal produced according to such a method of the invention is low in possibility to form a twin and is excellent in quality; therefore, the crystal can be suitably used as a substrate of a semiconductor device.

What is claimed is:

1. A production method for an InP single crystal having a cone portion and a constant diameter portion subsequent to the cone portion with a liquid encapsulated Czochralski method,
wherein when, in a section including an axial line of the InP single crystal, an angle formed between the axial line and a tangent to an outline of the cone portion is a cone angle, a period in which the cone angle is larger than a twinning angle is set during growth of the cone portion and in addition, during the period, a diameter increasing rate of the cone portion is gradually raised.

2. A production method for an InP single crystal according to claim 1, wherein the cone angle is larger than the twinning angle and a diameter increasing rate of the cone portion is also gradually raised through a period from when a diameter of the cone portion takes 10 mm till the diameter thereof reaches 70% of a diameter of the constant diameter portion.

3. A production method for an InP single crystal according to claim 2, wherein when in a section including an axial line of the InP single crystal, x axis is selected in the axial direction of the InP single crystal and r axis is selected in a radial direction of the InP single crystal, and an outline of the cone portion is expressed as a function of x and r, the cone portion is formed so that the function expressing an outline of the cone portion satisfies a relation of 0<d²r/dx²≦0.1 through a period from when a diameter of the cone portion takes 10 mm till the diameter thereof reaches 70% of a diameter of the constant diameter portion.

4. A production method for an InP single crystal according to claim 1, wherein the InP single crystal with a crystal orientation of <100> is grown and a twinning angle is 35.3°.

5. A production method for an InP single crystal according to claim 2, wherein the InP single crystal with a crystal orientation of <100> is grown and a twinning angle is 35.3°.

6. A production method for an InP single crystal according to claim 3, wherein the InP single crystal with a crystal orientation of <100> is grown and a twinning angle is 35.3°.

7. A production method for an InP single crystal according to claim 1, wherein the cone portion is formed so that the cone angle does not exceed 70°.

8. A production method for an InP single crystal according to claim 2, wherein the cone portion is formed so that the cone angle does not exceed 70°.

9. A production method for an InP single crystal according to claim 3, wherein the cone portion is formed so that the cone angle does not exceed 70°.

10. A production method for an InP single crystal having a cone portion and a constant diameter portion subsequent to the cone portion with an liquid encapsulated Czochralski method,
wherein when, in a section including an axial line of the InP single crystal, an angle formed between the axial line and a tangent to an outline of the cone portion is a cone angle, the cone angle is larger than a twinning angle through a period from when a diameter of the cone portion takes 10 mm till the diameter thereof reaches 70% of a diameter of the constant diameter portion.

11. A production method for an InP single crystal according to claim 10, wherein the cone portion is formed so that the cone angle does not exceed 70°.

12. An InP single crystal comprising: a cone portion and constant diameter portion subsequent thereto, and
when, in a section including an axial line of the InP single crystal, an angle formed between the axial line and a tangent to an outline of the cone portion is a cone angle, a region in which a diameter increasing rate of the cone portion gradually increases toward the constant diameter portion side is present in a region in which the cone angle is larger than a twinning angle.

13. An InP single crystal according to claim 12, wherein the cone angle is larger than the twinning angle and a diameter increasing rate of the cone portion in the axial direction gradually increases toward the constant diameter portion side in a region where a diameter of the cone portion is 10 mm or more and 70% or less of a diameter of the constant diameter portion.

14. An InP single crystal according to claim 13, wherein when, in a section including the axial line, x axis is selected in the axial direction of the InP single crystal and r axis is selected in a radial direction of the InP single crystal, and an outline of the cone portion is expressed as a function of x and r, the function expressing an outline of the cone portion satisfies a relation of 0<d²r/dx²≦0.1 in a region where a diameter of the cone portion is 10 mm or more and 70% or less of a diameter of the constant diameter portion.

15. An InP single crystal according to claim 12, having a crystal orientation of <100> and the twinning angle of 35.30.

16. An InP single crystal according to claim 13, having a crystal orientation of <100> and the twinning angle of 35.3°.

17. An InP single crystal according to claim 14, having a crystal orientation of <100> and the twinning angle of 35.3°.

18. An InP single crystal according to claim 12, wherein the cone angle is 70° or less in the cone portion.

19. An InP single crystal according to claim 13, wherein the cone angle is 70° or less in the cone portion.

20. An InP single crystal according to claim 14, wherein the cone angle is 70° or less in the cone portion.

21. An InP single crystal comprising: a cone portion and constant diameter portion subsequent thereto, and
when, in a section including an axial line of the InP single crystal, an angle formed between the axial line and a tangent to an outline of the cone portion is a cone angle, the cone angle is larger than a twinning angle in a region where a diameter of the cone portion is 10 mm or more and 70% or less of a diameter of the constant diameter portion.

22. An InP single crystal according to claim 21, wherein the cone angle is 70° or less in the cone portion.
